(19) United States
(12) Patent Application Publication
(10) Pub. No.: US 2006/0199335 A1
(43) Pub. Date: Sep. 7, 2006

(54) Electronic devices including non-volatile memory structures and processes for forming the same

(75) Inventors: Rajesh A. Rao, Austin, TX (US); Ramachandran Muralidhar, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: Freescale Semiconductor, Inc., Austin, TX (US)

(21) Appl. No.: 11/071,977

(22) Filed: Mar. 4, 2005

(51) Int. Cl. H01L 21/336; H01L 21/8238

(52) U.S. Cl. 438/258; 438/257; 438/201

(57) ABSTRACT

An electronic device can include an NVM structure and a gate electrode outside an NVM array. In one embodiment, a first gate dielectric layer and a first gate electrode layer are formed before forming NVM cells within an NVM array. The first gate electrode layer helps to protect the first gate dielectric layer from becoming thinner or thicker during subsequent processing used to form NVM cells. In another embodiment, NVM structures and transistor structures can be formed where the NVM structures have one more spacer adjacent to the NVM structures as compared to the transistor structures.

### BACKGROUND

1. Field of the Disclosure

The present disclosure relates to electronic devices and processes for forming them, and more particularly to electronic devices including non-volatile structures and processes for forming the same.

2. Description of the Related Art

Integration of non-volatile memory (“NVM”) arrays into electronic devices, such as integrated circuits, is becoming more difficult as the number of gate dielectric layers present within the electronic device continues to increase. Currently, three or more different gate dielectric layers may be formed. The NVM array may be fabricated while other areas of the electronic device are protected. After the NVM array has been fabricated, the electronic components (e.g., transistors, resistors, capacitors, etc.) within the other areas of the electronic device are fabricated. Such processing can include forming and removing portions of gate dielectric layers before a final gate dielectric layer is formed. The surface of the substrate where the final gate dielectric is formed may be roughened by the repeated formation and removal of the other gate dielectric layers.

Another process can be used where the gate dielectric layers for all areas outside the NVM array are formed before forming the NVM array. However, the gate electrodes for the transistors outside the NVM array are not formed until after the NVM array has been fabricated. During the NVM processing, the thinnest of the gate dielectric layers may be thickened.

### BRIEF DESCRIPTION OF THE DRAWINGS

Embodiments are illustrated by way of example and not limitation in the accompanying figures.

FIG. 1 includes illustrations of cross-sectional views of regions of a substrate after doping portions that will become well regions within a high-voltage region and input/output region.

FIG. 2 includes illustrations of cross-sectional views of the regions of FIG. 1 after doping a portion that will become a well region within a logic region.

FIG. 3 includes illustrations of cross-sectional views of the regions of FIG. 2 after forming a gate dielectric layer over the logic portion.

FIG. 4 includes illustrations of cross-sectional views of the regions of FIG. 3 after forming a first gate electrode layer and a first anti-reflective layer.

FIG. 5 includes illustrations of cross-sectional views of the regions of FIG. 4 after doping a portion that will become a well region within an NVM array.

FIG. 6 includes illustrations of cross-sectional views of the regions of FIG. 5 after forming an NVM stack and a mask layer.

FIG. 7 includes illustrations of cross-sectional views of the regions of FIG. 6 after patterning the NVM stack and doping portions of the NVM array that will become extension regions.

FIG. 8 includes illustrations of cross-sectional views of the regions of FIG. 7 after forming a gate electrode mask.

FIG. 9 includes illustrations of cross-sectional views of the regions of FIG. 8 after patterning the first gate electrode layer and doping portions of the high-voltage and input/output regions that will become extension regions.

FIG. 10 includes illustrations of cross-sectional views of the regions of FIG. 9 after doping portions of the logic region that will become extension regions.

FIG. 11 includes illustrations of cross-sectional views of the regions of FIG. 10 after forming additional spacers, performing source/drain (“S/D”) doping, and performing a S/D anneal cycle.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments.

### DETAILED DESCRIPTION

An electronic device can include an NVM structure and a gate electrode outside an NVM array. In one embodiment, a first gate dielectric layer and a first gate electrode layer are formed before forming NVM cells within an NVM array. The first gate electrode layer helps to protect the first gate dielectric layer from becoming thinner or thicker during subsequent processing used to form NVM cells. In another embodiment, NVM structures and transistor structures can be formed where the NVM structures have one more spacer adjacent to the NVM structures as compared to the transistor structures.

In a first aspect, a process for forming an electronic device includes forming a first gate dielectric layer over a first region of a substrate, forming a first gate electrode layer over the first gate dielectric layer, and forming a non-volatile memory stack over a second region of the substrate after forming the first gate electrode layer.

In one embodiment of the first aspect, the process further includes forming a second gate dielectric layer over a third region of the substrate, wherein the second gate dielectric layer has thickness different from the first gate dielectric layer. In another embodiment, the process further includes forming all gate dielectric layers, including the first gate dielectric layer, for all transistors other than any gate dielectric layer within the non-volatile memory stack, before forming the non-volatile memory stack.

In still another embodiment of the first aspect, the process further includes patterning the first gate electrode layer to define an opening before forming the non-volatile memory stack. In a particular embodiment, forming the non-volatile memory stack includes forming a charge storage stack over the substrate and within the opening within the first gate electrode layer, and forming a control gate electrode layer over the charge storage stack. In a more particular embodiment, the charge storage stack includes nanocrystals.

In a further embodiment of the first aspect, the process further includes patterning the non-volatile memory stack to define a non-volatile memory structure. The process also includes patterning the first gate electrode layer to define a first transistor structure that includes the first gate dielectric layer and a portion of the first gate electrode layer, wherein patterning the first gate electrode layer is performed after patterning the non-volatile memory stack. In a particular embodiment, the process further includes forming a sidewall spacer adjacent to side of the non-volatile memory structure before patterning the first gate electrode layer. In another particular embodiment, the process further includes forming an insulating layer over the substrate after patterning the first gate electrode layer and etching the insulating layer. A first spacer lies adjacent to a side of the non-volatile memory structure, a second spacer lies adjacent to a side of the first transistor structure, and each of the first and second spacers includes a portion of the insulating layer.

In still a further embodiment of the first aspect, the process further includes patterning the NVM stack to define an NVM gate structure, oxidizing a portion of a side of the NVM gate structure, doping portions of the substrate adjacent to the side of the NVM gate structure before depositing a layer along the side of the NVM gate structure, and forming a sidewall spacer along the side of the NVM gate structure after doping the portions of the substrate.

In a second aspect, an electronic device includes a substrate and a non-volatile memory structure overlying the substrate, wherein the non-volatile memory structure includes a first gate dielectric layer. The electronic device also includes a first spacer having a generally parabolic outer surface, wherein the first spacer lies laterally adjacent to a side of the first gate dielectric layer within the non-volatile memory structure. The electronic device further includes a first transistor structure overlying the substrate and spaced apart from the non-volatile memory structure, wherein the first transistor structure includes a second gate dielectric layer. The electronic device still further includes second spacers each having a generally parabolic outer surface, wherein one of the second spacers lies laterally adjacent to a side of the second gate dielectric layer within the first transistor structure, and another second spacer lies laterally adjacent to the generally parabolic outer surface of the first spacer.

In one embodiment of the second aspect, the non-volatile memory structure includes a charge storage stack that includes the first gate dielectric layer and nanocrystals. In another embodiment, the first and second gate dielectric layers lie at approximately the same elevation along a primary surface of the substrate.

In a third aspect, a process for forming an electronic device includes forming a non-volatile memory structure over a substrate, forming a first insulating layer over the substrate after forming the non-volatile memory structure, etching the first insulating layer to form a first spacer along a side of the non-volatile memory structure, forming a first transistor structure over the substrate and spaced apart from the non-volatile memory structure after etching the first insulating layer, forming a second insulating layer over the substrate after forming the first transistor structure, and etching the second insulating layer to form a second spacer along the side of the first transistor structure, wherein the first spacer includes a portion of the second insulating layer lying along a side of the first spacer.

In one embodiment of the third aspect, the process further includes forming a first gate dielectric layer over the substrate before forming the non-volatile memory structure, and patterning the first gate dielectric layer to define an opening. Forming the non-volatile memory structure includes forming a non-volatile memory stack within the opening. In a particular embodiment, the process further includes forming a second gate dielectric layer over the substrate after forming the first gate dielectric layer, wherein the second gate dielectric layer has thickness different from the first gate dielectric layer. In another particular embodiment, forming the first transistor structure includes forming a first gate electrode layer over the first gate dielectric layer before forming the non-volatile memory structure, and patterning the first gate electrode layer to define an opening before forming the non-volatile memory structure. Forming the non-volatile memory structure includes forming a non-volatile memory stack within the opening within the first gate electrode layer. In still another particular embodiment, the process further includes forming a first gate electrode layer over the first gate dielectric layer before forming the non-volatile memory structure, and patterning the first gate electrode layer after forming the non-volatile memory structure to define a first transistor structure that includes the first gate dielectric layer and a portion of the first gate electrode layer

In another embodiment of the third aspect, the process further includes forming all get dielectric layers, including the first gate dielectric layer, for all transistors other than any non-volatile memory cell, before forming the non-volatile memory structure. In still another embodiment, the non-volatile memory structure includes a charge storage stack that includes nanocrystals.

Before addressing details of embodiments described below, some terms are defined or clarified. Group numbers corresponding to columns within the Periodic Table of the elements use the “New Notation” convention as seen in the CRC Handbook of Chemistry and Physics, 81^{st} Edition (2000).

The term “stack” is intended to mean a plurality of layers or a plurality of at least one layer and at least one structure (e.g., nanocrystals), wherein the plurality of layers or plurality of layer(s) and structure(s) provides an electronic function. For example, a non-volatile memory stack can include layers used to form at least part of a non-volatile memory cell. A stack may be part of a larger stack. For example, a non-volatile memory stack can include a charge storage stack that is used to store charge within a non-volatile memory cell.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Additionally, for clarity purposes and to give a general sense of the scope of the embodiments described herein, the use of the terms “a” or “an” are employed to describe one or more articles to which “a” or “an” refers. Therefore, the description should be read to include one or at least one whenever “a” or “an” is used, and the singular also includes the plural unless it is clear that the contrary is meant otherwise.

Unless otherwise defined, all technical and scientific terms used herein have the same meaning as commonly understood by one of ordinary skill in the art to which this invention belongs. All publications, patent applications, patents, and other references mentioned herein are incorporated by reference in their entirety. In case of conflict, the present specification, including definitions, will control. In addition, the materials, methods, and examples are illustrative only and not intended to be limiting.

Other features and advantages of the invention will be apparent from the following detailed description, and from the claims.

To the extent not described herein, many details regarding specific materials, processing acts, and circuits are conventional and may be found in textbooks and other sources within the semiconductor and microelectronic arts.

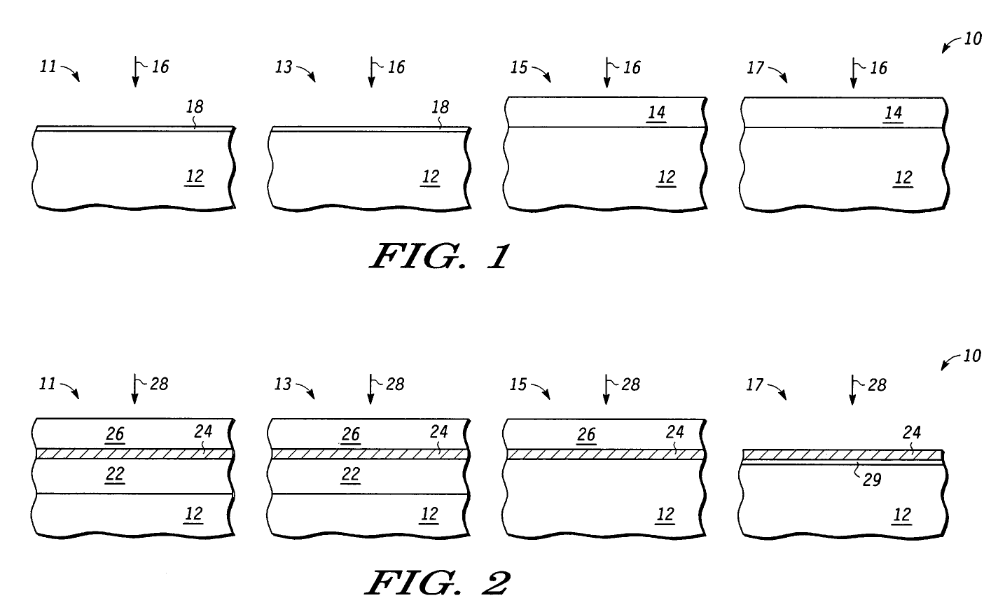

FIG. 1 includes illustrations of portions of a substrate 12 within an electronic device 10 after forming a mask layer over some of the regions of the substrate 12. The substrate 12 can include a monocrystalline semiconductor wafer, a semiconductor-on-insulator wafer, a flat panel display (e.g., a silicon layer over a glass plate), or other substrate that is conventionally used to form electronic devices. High-voltage (“HV”) components will be formed within an HV region 11, input/output (“I/O”) components will be formed within an I/O region 13, NVM memory cells will be formed within the NVM array 15, and logic components will be formed within a logic region 17.

A mask 14 is formed over the NVM array 15 and logic region 17, and the HV region 11 and I/O region 13 are exposed. The mask 14 can include a conventional resist material. The conventional resist material may be patterned using a conventional lithographic technique. A first dopant is introduced into the exposed portions of the substrate 12 within the HV region 11 and I/O region 13 to form doped regions 18 that will be subsequently driven into the substrate 12 to form well regions. The first dopant may be a p-type dopant (e.g., boron) or an n-type dopant (e.g., phosphorus or arsenic). In one embodiment, the first dopant can be introduced using ion implantation (illustrated as arrows 16 in FIG. 1). In a particular embodiment, the ion implantation may be performed at an energy of at least 20 KeV and a dose no higher than 5E13 ions/cm². The mask 14 prevents a significant amount of the first dopant from entering the substrate 12 within the NVM array 15 and logic region 17. Although not illustrated, an implant screen (e.g., a silicon dioxide or silicon nitride layer having a thickness no greater than 20 nm) may be formed before the mask 14 is formed. The implant screen can help to reduce the likelihood of implant channeling. After the doped regions 18 are formed, the mask 14 is removed using a conventional technique.

An optional well drive cycle is performed to drive the dopant from the doped regions 18 further into the substrate 12 to form the well regions 22 within the HV region 11 and the I/O region 13, as illustrated in FIG. 2. A first gate dielectric layer 24 is formed over the substrate 12, including the HV region 11, the I/O region 13, the NVM array 15, and the logic region 17. The first gate dielectric layer 24 may be thermally grown using an ambient including steam or oxygen, or may be deposited using a conventional chemical vapor deposition technique, physical vapor deposition technique, atomic layer deposition technique, or a combination thereof. The first gate dielectric layer 24 can include one or more films of silicon dioxide, silicon nitride, silicon oxynitride, a high-k material (e.g., k greater than 7), or any combination thereof. The high-k material can include HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrO₂, other Hf-containing or Zr-containing dielectric material, a doped version of any of the foregoing (lanthanum doped, niobium doped, etc.), or any combination thereof. As used throughout this specification, the sum of the lettered subscripts for any specific compound is 1. The first gate dielectric layer 24 has a thickness in a range of approximately 5 to 50 nm in a substantially completed electronic device.

The mask 26 is formed over the HV region 11, I/O region 13, and NVM array 15, and the logic region 17 is exposed. The mask 26 can include a conventional resist material. The conventional resist material may be patterned using a conventional lithographic technique. A second dopant is introduced into the exposed portions of the substrate 12 within the logic region 17 to form a doped region 29 that will be subsequently driven into the substrate 12 to form another well region. The second dopant may be a p-type dopant (e.g., boron) or an n-type dopant (e.g., phosphorus or arsenic). In one embodiment, the second dopant can be introduced using ion implantation (illustrated as arrows 28 in FIG. 2). In a particular embodiment, the ion implantation may be performed at an energy of at least 20 KeV and a dose no higher than 5E13 ions/cm². The mask 26 prevents a significant amount of the second dopant from entering the substrate 12 within the HV region 11, I/O region 13, and NVM array 15. After the doped regions 29 are formed, the mask 26 is removed using a conventional technique.

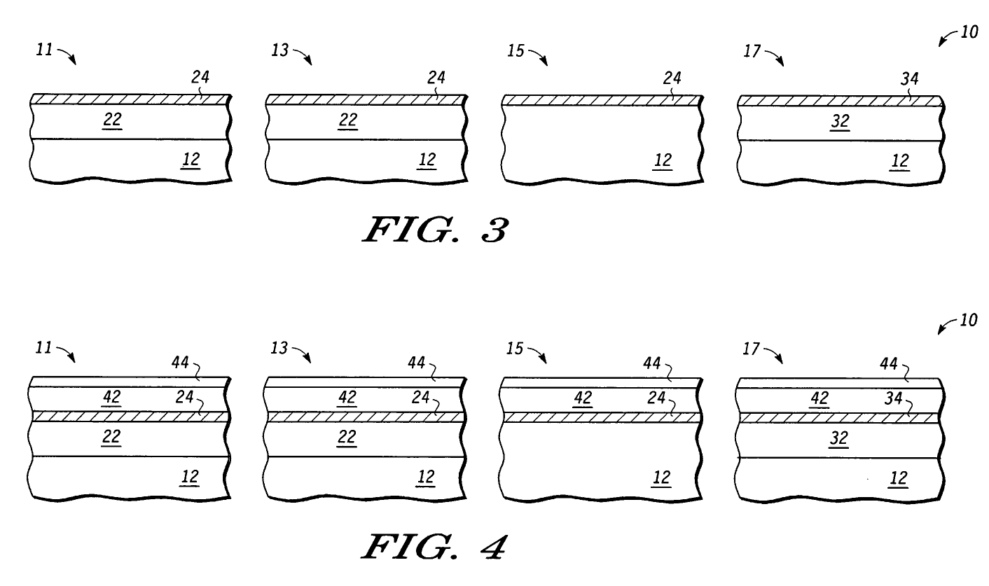

An optional well drive cycle is performed to drive the dopant from the doped regions 29 further into the substrate 12 to form the well region 32 within the logic region 17, as illustrated in FIG. 3. A second gate dielectric layer 34 is formed over the substrate 12, including the logic region 17. The second gate dielectric layer 34 may be thermally grown using an ambient, including steam or oxygen or deposited using a convention chemical vapor deposition technique, physical vapor deposition technique, atomic layer deposition technique, or a combination thereof. The second gate dielectric layer 34 can include one or more films of silicon dioxide, silicon nitride, silicon oxynitride, a high-k material (e.g., k greater than 7), or any combination thereof. The high-k material can include HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrO₂, other Hf-containing or Zr-containing dielectric material, a doped version of any of the foregoing (lanthanum doped, niobium doped, etc.), or any combination thereof. The second gate dielectric layer 34 has a thickness in a range of approximately 1 to 20 nm in the substantially completed electronic device. In one embodiment, the first gate dielectric layer 24 becomes thicker during the formation of the second gate dielectric layer 34.

A first gate electrode layer 42 and a first anti-reflective layer 44 are formed over the substrate 12, as illustrated in FIG. 4. The first gate electrode layer 42 can include one or more semiconductor-containing or metal-containing films that are deposited over the substrate 12. In one embodiment, first gate electrode layer 42 includes polysilicon or amorphous silicon deposited by a chemical vapor deposition process, but may include other materials or may be deposited by other processes in other embodiments. In one embodiment, the first gate electrode layer 42 is doped when deposited, and in another embodiment, is doped after it is deposited. In one embodiment, the thickness of the first gate electrode layer 42 is in a range of 50 to 300 nm.

The first anti-reflective layer 44 can include one or more nitride-containing films that are deposited over the first gate electrode layer 42. In one embodiment, first anti-reflective layer 44 includes silicon nitride, silicon-rich silicon nitride, a silicon oxynitride, a metal-containing nitride (e.g., TiN), a metal-containing oxynitride (e.g., TiₐO_{b}N_{c}), a metal-silicon nitride (e.g., TaₐSi_{b}N_{c}), a metal-silicon oxynitride (e.g., TaₐSi_{b}O_{c}N_{d}), or any combination thereof. The first anti-reflective layer 44 can be deposited by a chemical or physical vapor deposition process. In one embodiment, the thickness of the first anti-reflective layer 44 is in a range of 5 to 50 nm.

A mask 52 is formed over anti-reflective layer 44 within the HV region 11, I/O region 13, and logic region 17, but is not formed over the NVM array 15, as illustrated in FIG. 5. The mask 52 can include a conventional resist material. The conventional resist material may be patterned using a conventional lithographic technique. Portions of the first anti-reflective layer 44 and first gate electrode layer 42 are removed from the NVM array 15 by etching portions of those layers. The etching may be performed isotropically or anisotropically, as a wet etch, dry etch, or any combination of the foregoing. In one embodiment, the etching is performed as a dry etch using endpoint detection when the first gate dielectric layer 24 within the NVM array 15 becomes exposed. An optional timed overetch can be used to account for nonuniform etching across the substrate 12.

A third dopant is introduced into the exposed portions of the substrate 12 within the NVM array 15 to form a doped region 56 that will be subsequently driven into the substrate 12 to form yet another well region. The third dopant may be a p-type dopant (e.g., boron) or an n-type dopant (e.g., phosphorus or arsenic). In one embodiment, the third dopant can be introduced using ion implantation (illustrated as arrows 54 in FIG. 5). The mask 52 prevents a significant amount of the dopant from entering the substrate 12 within the HV region 11, I/O region 13, and logic region 17. After the doped region 56 is formed, the mask 52 is removed using a conventional technique.

In an alternative embodiment, the mask 52 may be removed before the third dopant is introduced into the exposed portions of the substrate 12. The combination of the first gate electrode layer 42 and first anti-reflective layer 44 can prevent a significant amount of dopant from reaching the well regions 22 and 32. If ion implantation is used for the third dopant, the energy of the ion implant can be selected to meet the needs or desires of the electronic device fabricator.

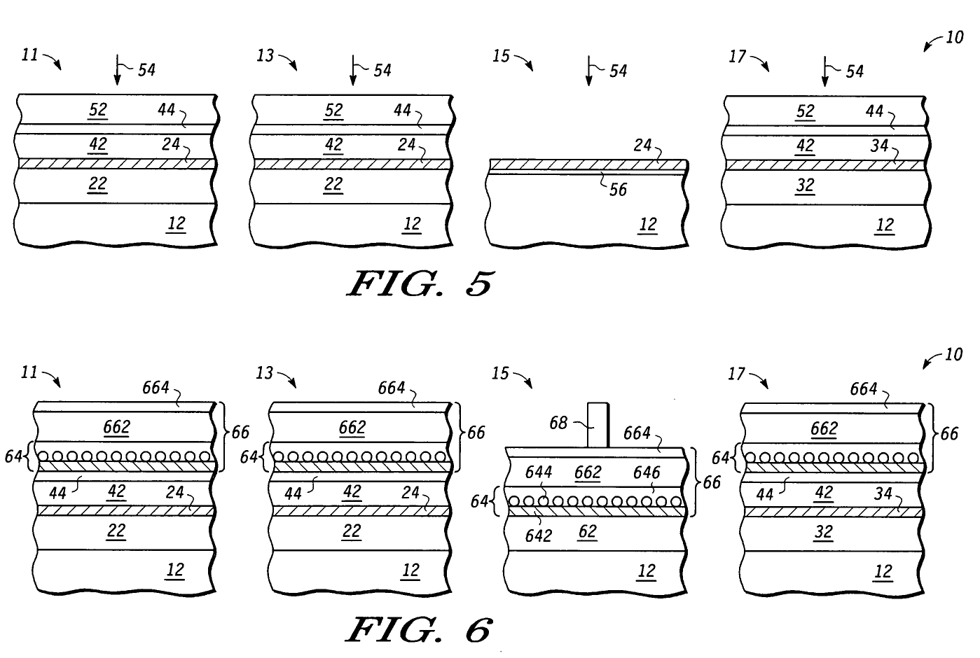

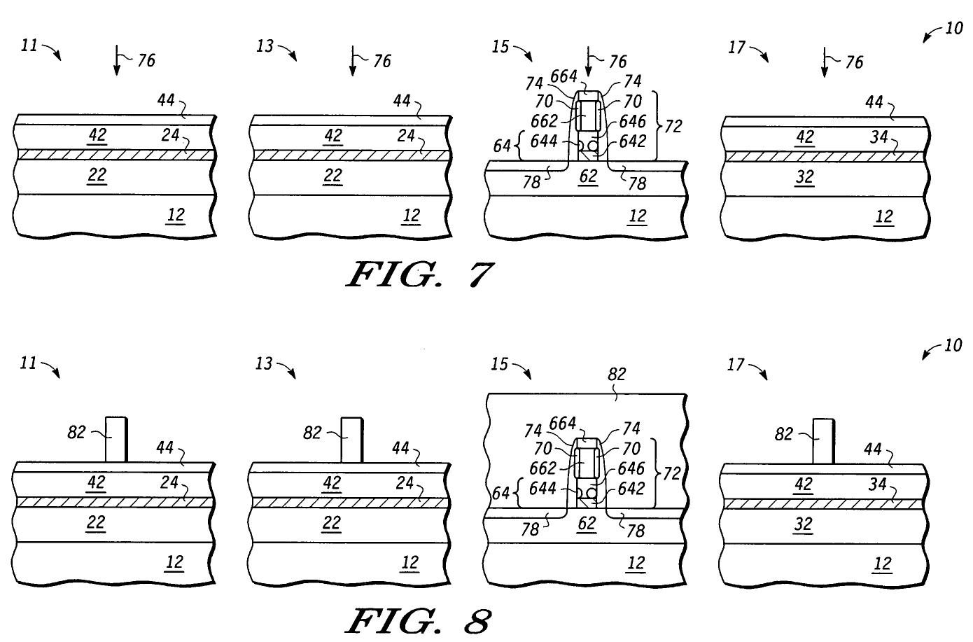

A third well drive cycle is performed to drive the dopant from the doped region 56 further into the substrate 12 to form the well region 62 within the NVM array 15, as illustrated in FIG. 6. The first gate dielectric layer 24 is removed using a conventional method.

An NVM stack 66 and a mask 68 are formed over the substrate 12, as illustrated in FIG. 6. The non-volatile memory stack 66 includes a charge storage stack 64, a control gate electrode layer 662, and a second anti-reflective layer 664. The charge storage stack 64 includes a third gate dielectric layer 642, a charge storage layer 644, and an interlevel dielectric layer 646.

The third gate dielectric layer 642 is formed over the substrate 12, including the NVM array 15, as illustrated in FIG. 6. In one embodiment, the third gate dielectric layer 642 is a tunnel oxide that allows Fowler-Nordheim tunneling to be used for programming the NVM array 15, erasing the NVM array 15, or both. The third gate dielectric layer 642 may be thermally grown using an ambient including steam or oxygen or deposited using a convention chemical vapor deposition technique, physical vapor deposition technique, atomic layer deposition technique, or a combination thereof. If the third gate dielectric layer 642 is thermally grown, it is not formed over the first anti-reflective layer 44. If the third gate dielectric layer is deposited, it is deposited over substantially all of the substrate 12. The third gate dielectric layer 642 can include one or more films of silicon dioxide, silicon nitride, silicon oxynitride, a high-k material (e.g., k greater than 7), or any combination thereof. The high-k material can includes HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrO₂, other Hf-containing or Zr-containing dielectric material, a doped version of any of the foregoing (lanthanum doped, niobium doped, etc.), or any combination thereof. The third gate dielectric layer 642 has a thickness in a range of approximately 2 to 20 nm in the substantially completed electronic device.

The charge storage layer 644 is formed by depositing nanocrystals (also called discontinuous storage elements or quantum dots) or a floating gate electrode layer over the third gate dielectric layer 642. The charge storage layer 644 can include a material capable of storing a charge, such as polysilicon, amorphous silicon, a nitride, or a metal-containing material. The charge storage layer 644 may be undoped, doped during deposition, or doped after deposition. In one embodiment, the charge storage layer 644 includes nanocrystals that are no greater than 10 nm in any dimension. In another embodiment, the nanocrystals can be larger, however, the nanocrystals are not formed so large as to form a continuous structure (i.e., nanocrystals are fused together). In still another embodiment, the charge storage layer 644 is a floating gate electrode layer. The floating gate electrode layer can include one or more semiconductor-containing, nitrogen-containing, or metal-containing films. In one embodiment, the floating gate electrode layer includes polysilicon or amorphous silicon deposited by a chemical vapor deposition process, but may include other materials or may be deposited by other processes in other embodiments. In one embodiment, the floating gate electrode layer is doped when deposited, and in another embodiment, is doped after it is deposited. In one embodiment, the thickness of the floating gate electrode layer is in a range of 50 to 300 nm.

The interlevel dielectric layer 646 can include one or more dielectric films, any of which may be thermally grown or deposited. The interlevel dielectric layer 646 can include silicon dioxide, silicon oxynitride, an oxide-nitride-oxide stack, or a high-K dielectric material, or any combination thereof. The high-k material can include HfₐO_{b}N_{c}, HfₐSi_{b}O_{c}, HfₐSi_{b}O_{c}N_{d}, HfₐZr_{b}O_{c}N_{d}, HfₐZr_{b}Si_{c}O_{d}Nₑ, HfₐZr_{b}O_{c}, ZrₐSi_{b}O_{c}, ZrₐSi_{b}O_{c}N_{d}, ZrO₂, other Hf-containing or Zr-containing dielectric material, a doped version of any of the foregoing (lanthanum doped, niobium doped, etc.), or any combination thereof. In one embodiment, the interlevel dielectric layer 646 is formed by a conventional deposition technique (e.g., chemical of physical vapor deposition). In an alternative embodiment where the charge storage layer 644 includes a metal, such as hafnium or titanium, the interlevel dielectric layer 646 can be formed from the oxidation of part of the charge storage layer 644. In one embodiment, the thickness of the interlevel dielectric layer 646 is in a range of 1-20 nm.

The control gate electrode layer 662 can include one or more semiconductor-containing or metal-containing films that are deposited over the substrate 12. In one embodiment, control gate electrode layer 662 includes polysilicon or amorphous silicon deposited by a chemical vapor deposition process, but may include other materials or may be deposited by other processes in other embodiments. In one embodiment, the control gate electrode layer 662 is doped when deposited, and in another embodiment, is doped after it is deposited. In one embodiment, the thickness of the control gate electrode layer 662 is in a range of 50 to 300 nm, and in a finished device, the control gate electrode layer 662 has a dopant concentration of at least 1E19 atoms/cm³.

The second anti-reflective layer 664 can include one or more nitride-containing films that are deposited over the control gate electrode layer 662. In one embodiment, the second anti-reflective layer 664 includes silicon nitride, silicon-rich silicon nitride, a silicon oxynitride, a metal-containing nitride (e.g., TiN), a metal-containing oxynitride (e.g., TiₐO_{b}N_{c}), a metal-silicon nitride (e.g., TaₐSi_{b}N_{c}), a metal-silicon oxynitride (e.g., TaₐSi_{b}O_{c}N_{d}), or any combination thereof. The second anti-reflective layer 664 can be deposited by a chemical or physical vapor deposition process. In one embodiment, the thickness of the second anti-reflective layer 664 is in a range of 5 to 50 nm.

A mask 68 is formed over the second anti-reflective layer 664 within the NVM array 15 as illustrated in FIG. 6. The mask corresponds to regions where NVM structures for NVM memory cells within the NVM array 15 are defined. The mask can include a conventional resist material. The conventional resist material may be patterned using a conventional lithographic technique.

Portions of the NVM stack 66 not covered by the mask 68 are removed by etching those portions of the NVM stack 66. The etch is typically performed using more than one portion. Each of the portions may be performed isotropically or anisotropically, as a wet etch or dry etch, or any combination of the foregoing. In one embodiment, the etching is performed using at least three portions. The first portion removes exposed portions of the second anti-reflective layer 664. The first portion may be timed or may use endpoint detection. The second portion removes exposed portions of the control gate electrode layer 662. The second portion may be timed or use endpoint detection. An optional timed overetch may be used to account for etching non-uniformity across the surface of the substrate 12.

The rest of the etching for the NVM stack 66 can vary depending on the composition of the layers within the charge storage stack 64. In one embodiment, the charge storage layer 644 includes nanocrystals, and the interlevel dielectric layer 646 and the third gate dielectric layer 642 include oxide films. A dilute HF solution (e.g., at least 10 parts H₂O per part HF) can be used to remove portions of the charge storage stack 64 that are not covered by the mask 68. In another embodiment, the charge storage layer 644 includes nanocrystals, the interlevel dielectric layer 646 includes a nitride film, and the third gate dielectric layer 642 includes an oxide film. In this embodiment, a wet or dry etch can be used to remove the nitride film within the interlevel dielectric layer 646, and a dilute HF solution can be used to remove the charge storage layer 644 and third gate dielectric layer 642. In still another embodiment, the third gate dielectric layer 642 includes a nitride. After the interlevel dielectric layer 646 is etched, a H₃PO₄ solution can be used to remove the charge storage layer 644 and third gate dielectric layer 642.

In another embodiment, the charge storage layer 644 includes a floating gate electrode layer. A third portion of the etch removes exposed portions of the interlevel dielectric layer 646. The third portion may be timed or use endpoint detection. A fourth portion removes exposed portions of the floating gate electrode layer. The fourth portion may be timed or use endpoint detection. An optional timed overetch may be used to account for etching non-uniformity across the surface of the substrate 12. A fifth portion removes exposed portions of the third gate dielectric layer 642. The fifth portion may be performed as a wet or dry etch.

In one particular embodiment, the third gate dielectric layer 642 is SiO₂, the charge storage layer 644 is silicon nanocrystals, the interlevel dielectric layer 646 is SiO₂, the control gate electrode layer 662 is polysilicon, and the second anti-reflective layer 664 is silicon-rich silicon nitride.

In one exemplary, non-limiting embodiment, portions of the second anti-reflective layer 664 are removed using a timed anisotropic plasma etch with one or more fluorine-based gases, such as SF₆, CF₄, or the like, and one or more optional noble gases (e.g., He, Ne, Ar, or the like) to provide at least some physical sputtering component to the etch. The time selected for the timed etch is selected to remove substantially all of the second anti-reflective layer 664 at locations not covered by the mask 68. The underlying control gate electrode layer 662 is then removed in a anisotropic plasma etch using one or more halogen-based gases, including fluorine (e.g., SF₆, CF₄, etc.), chlorine (e.g., Cl₂, HCl, etc.), bromine (e.g., HBr, Br₂), iodine (e.g., ICl₅, etc.), or any combination thereof. The etch chemistry, when etching the control gate electrode layer 662, can also include an optional O₂ flow. The control gate electrode layer 662 etch is selective to the underlying interlevel dielectric layer 646 and uses an endpoint detection system to stop the etch. An optional overetch is carried out using the same gas flows to reduce etch non-uniformity across the substrate 12. This overetch is a short timed etch. A dilute HF wet etch with physical agitation is used to remove the charge storage stack 64, including the nanocrystals within the charge storage layer 644. The physical agitation may be provided by a conventional megasonic or ultrasonic cleaning system. Alternatively, another timed plasma etch using any one or more of the halogen-based gases, as described with respect to the control gate electrode layer 662 can be used to remove any one or more of the layers within the charge storage stack 64. After reading this specification, skilled artisans will appreciate that many different etch chemistries and etching methods can be used when patterning the NVM stack 66 to achieve NVM structures.

After reading this specification, skilled artisans will appreciate that many different materials may be used for the layers within the NVM stack 66. The etch chemistries can depend on the various compositions of the layers. Some or all of the portions of the etch sequence can use etch chemistries that are selective to an underlying layer. For example, the etch chemistry used for the portion of the etch that removes exposed portions of the control gate electrode layer 662 can etch the material within the control gate electrode layer 662 at a significantly higher rate as compared to the interlevel dielectric layer 646, and the etch chemistry used for the portion of the etch that removes exposed portions of the third gate dielectric layer 642 can etch the material within the third gate dielectric layer 642 at a significantly higher rate as compared to the material within the well region 62. Some portions of the etch sequence can use etch chemistries that are not selective to an underlying layer. For example, the second anti-reflective layer 664 can include silicon-rich silicon nitride, and the control gate electrode layer 662 can include polysilicon. In this particular embodiment, etch selectivity between the second anti-reflective layer 664 and the control gate electrode layer 662 is not critical. Thus, the type of etch performed (wet versus dry), the etch chemistry, and whether a timed etch, endpoint detection or a combination of endpoint with a timed overetch is used can be varied to meet the needs and desires of the electronic device fabricator. After the NVM stack 66 has been patterned, the mask 68 is removed using a conventional technique.

Exposed sidewalls of the control gate electrode layer 662 are oxidized to form a protective oxide layer 70, as illustrated in FIG. 7. The protective oxide layer 70 has a thickness in range of approximately 1 to 5 nm. An optional set of spacers 74 is formed along the sides of the NVM structure 72. The set of spacers 74 can be formed by depositing an insulating layer (e.g., an oxide, a nitride, or an oxynitride) over the substrate 12 and anisotropically etching portions of the insulating layer. In one embodiment, the spacers 74 have a generally parabolic (curved) outer surface, and the width of the spacers 74 at their base is no more than 15 nm. The set of spacers 74 are formed along vertical or near vertical surfaces of the substrate 12, including adjacent to the sides of the NVM structure 72. Although not illustrated, the set of spacers 74 are also formed along the exposed sides of the first gate electrode layer 42 and first anti-reflective layer 44.

A fourth dopant is introduced into portions of the well region 62 to form doped regions 78. The doped regions 78 will become extension regions for the NVM cells within the NVM array 15. The fourth dopant may be a p-type dopant (e.g., boron) or an n-type dopant (e.g., phosphorus or arsenic). In one embodiment, the fourth dopant can be introduced using ion implantation (illustrated as arrows 76 in FIG. 7). The ion implantation is performed at an energy no greater than 50 KeV, and the dose is at least 1E14 ions/cm³. The combination of the first gate electrode layer 42 and first anti-reflective layer 44 prevents a significant amount of the dopant from entering the substrate 12 within the HV region 11, I/O region 13, and logic region 17.

A mask 82 is formed over the NVM array 15 and portions of the first anti-reflective layer 44 within the HV region 11, I/O region 13, and the logic region 17, as illustrated in FIG. 8. The mask corresponds to regions where gate structures for transistors outside the NVM array 15 are to be defined. The mask 82 can include a conventional resist material. The conventional resist material may be patterned using a conventional lithographic technique.

Portions of the first gate electrode layer 42 and first anti-reflective layer 44 not covered by the mask 82 are removed by etching. The etch is typically performed using one or more portions. Each of the portions may be performed isotropically or anisotropically, as a wet etch, dry etch, or any combination of the foregoing. In one embodiment, the etching is performed using at least two portions. The first portion removes exposed portions of the first anti-reflective layer 44. The first portion may be timed or use endpoint detection. The second portion removes exposed portions of the first gate electrode layer 42. The second portion may be timed or use endpoint detection. An optional timed overetch may be used to account for etching non-uniformity across the surface of the substrate 12. An optional third portion can be used to remove portions of the first gate dielectric layer 24 and second gate dielectric layer 34. The third portion may be timed or use endpoint detection. An optional timed overetch may be used to account for etching non-uniformity across the surface of the substrate 12. The mask 82 is removed using a conventional technique.

In one particular embodiment, the first and second gate dielectric layers 24 and 34 are SiO₂, the first gate electrode layer 42 is polysilicon, and the first anti-reflective layer 44 is silicon-rich silicon nitride.

In one exemplary, non-limiting embodiment, portions of the first anti-reflective layer 44 are removed using a timed anisotropic plasma etch with one or more fluorine-based gases, such as SF₆, CF₄, or the like, and one or more optional noble gases (e.g., He, Ne, Ar, or the like) to provide some physical sputtering component to the etch. The time selected for the timed etch is selected to remove substantially all of the first anti-reflective layer 44 at locations not covered by the mask 82. The underlying first gate electrode layer 42 is then removed in an anisotropic plasma etch using one or more halogen-based gases, including fluorine (e.g., SF₆, CF₄, etc.), chlorine (e.g., Cl₂, HCl, etc.), bromine (e.g., HBr, Br₂), iodine (e.g., ICl₅, etc.), or any combination thereof. The etch chemistry when etching the control gate electrode layer 662 can also include an optional O₂ flow. The first gate electrode layer 42 etch is selective to the underlying gate dielectric layers 24 and 34, and uses an endpoint detection system to stop the etch. An optional overetch is carried out using the same gas flows to reduce etch non-uniformity across the substrate 12. This overetch is a short timed etch. After reading this specification, skilled artisans will appreciate that many different etch chemistries and etching methods can be used when patterning the first gate electrode layer 42 to achieve gate electrodes.

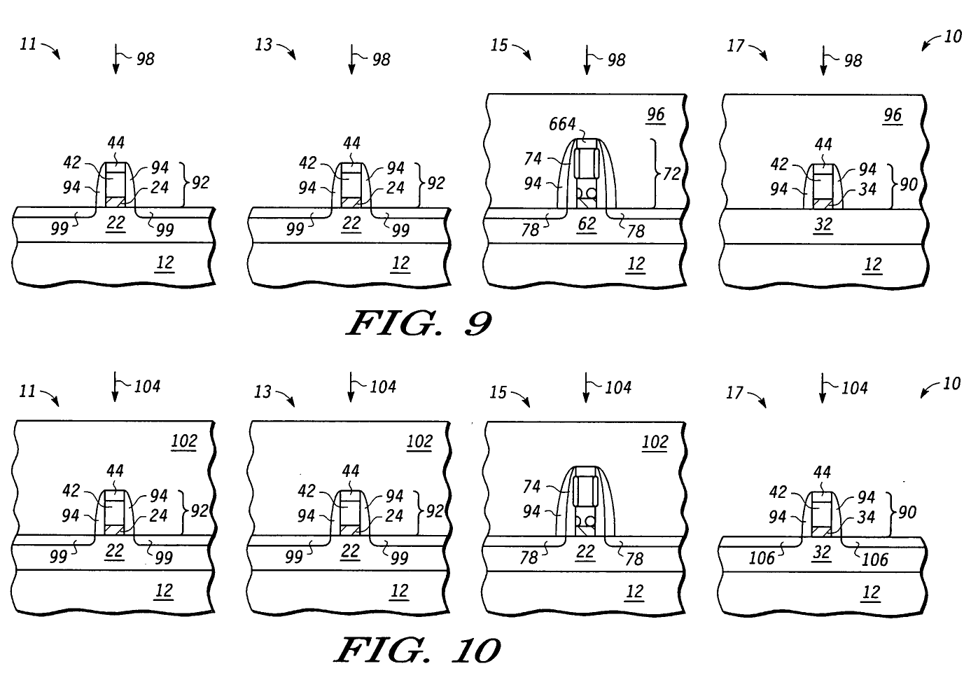

Remaining portions of the first anti-reflective layer 44 and second anti-reflective layer 664 are removed using a conventional technique. If exposed portions of the first gate dielectric layer 24 and second gate dielectric layer 34 have not been removed, they may be removed at this time. The exposed portions of the first gate dielectric layer 24 and second gate dielectric layer 34 can be removed using a conventional wet or dry etching technique. At this point in the process, gate structures 90 (within the logic region 17) and 92 (within the HV region 11 and I/O region 13) have been defined, as illustrated in FIG. 9.

Exposed sidewalls of the first gate electrode layer 42 can be oxidized to form a protective oxide layer (not illustrated). The protective oxide layer has a thickness in a range of approximately 1 to 20 nm. The protective oxide layer is optional and is not required.

A set of spacers 94 are formed along the sides of the spacers 74, and gate structures 90 and 92. The set of spacers 94 can be formed by depositing an insulating layer (e.g., an oxide, a nitride, or an oxynitride) over the substrate 12 and anisotropically etching portions of the insulating layer. In one embodiment, the spacers 94 have a generally parabolic (curved) outer surface, and the width of the spacers 94 at their base is no more than 15 nm. The set of spacers 94 are formed along vertical or near vertical surfaces of the substrate 12, including surfaces adjacent to the generally parabolic outer surfaces of the spacers 74, and along the gate structures 90 and 92.

A mask 96 is formed over the NVM array 15 and the logic region 17, as illustrated in FIG. 9. The mask 96 covers the NVM array 15 and logic region 17 and leaves the HV region 11 and I/O region 13 exposed. The mask 96 can include a conventional resist material. The conventional resist material may be patterned using a conventional lithographic technique.

A fifth dopant is introduced into the well regions 22 to form doped regions 99. The doped regions 99 will become extension regions for the transistors within the HV region 11 and I/O region 13. The fifth dopant may be a p-type dopant (e.g., boron) or an n-type dopant (e.g., phosphorus or arsenic). In one embodiment, the fifth dopant can be introduced using ion implantation (illustrated as arrows 98 in FIG. 9). The first gate electrode layer 42 prevents a significant amount of the dopant from entering portions of the well region 22 at locations covered by the gate structures 92 and spacers 94 within the HV region 11 and I/O region 13. The mask 96 prevents a significant amount of the dopant from entering the well region 62 within the NVM array 15 and the well region 32 within the logic region 17. After the doped regions 99 have been formed, the mask 96 is removed using a conventional technique.

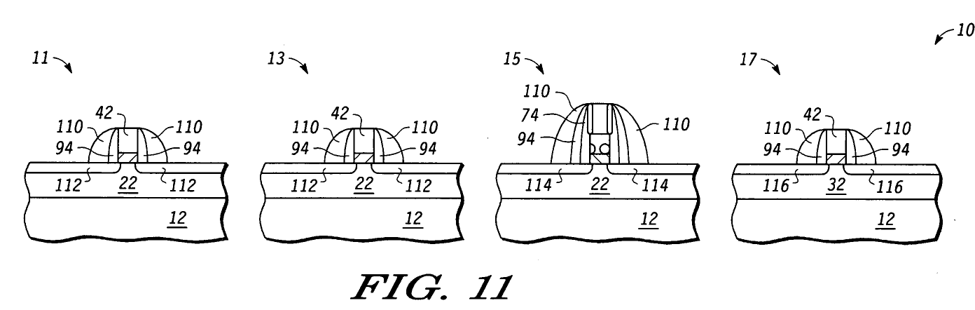

A mask 102 is formed over the substrate 12, except for the logic region 17, as illustrated in FIG. 10. The mask 102 can include a conventional resist material. The conventional resist material may be patterned using a conventional lithographic technique.

A sixth dopant is introduced into the well region 32 to form doped regions 106. The doped regions 106 will become extension regions for the transistors within the logic region 17. The sixth dopant may be a p-type dopant (e.g., boron) or an n-type dopant (e.g., phosphorus or arsenic). In one embodiment, the sixth dopant can be introduced using ion implantation (illustrated as arrows 104 in FIG. 10). The first gate electrode layer 42 prevents a significant amount of the dopant from entering portions of the well region 32 at locations covered by the gate structure 90 and spacers 94 within the logic region 17. The mask 102 prevents a significant amount of the dopant from entering the well regions 22 and 32 within the HV region 11, the I/O region 13, and the NVM array 15. After the doped regions 106 have been formed, the mask 102 is removed using a conventional technique.

A set of spacers 110 are formed along the sides of the spacers 94 that are adjacent to the gate structures 90 and 92 and NVM structure 72 as illustrated in FIG. 11. The set of spacers 110 can be formed by depositing an insulating layer (e.g., an oxide, a nitride, or an oxynitride) over the substrate 12 and anisotropically etching portions of the insulating layer. In one embodiment, the set of spacers 110 are formed along vertical or near vertical surfaces of the substrate 12, including surfaces adjacent to the generally parabolic outer surfaces of the spacers 94, and the width of the spacers 110 at their base is no more than 50 nm.

A seventh dopant is introduced into portions of the well regions 22, 32, and 62 to form doped regions (not illustrated). The doped regions will become S/D regions for the transistors and NVM memory cells within the electronic device 10. The seventh dopant may be a p-type dopant (e.g., boron) or an n-type dopant (e.g., phosphorus or arsenic). In one embodiment, the seventh dopant can be introduced using ion implantation. A thermal cycle is used to activate the dopants to form S/D regions 112, 114, and 116 as illustrated in FIG. 11. The S/D regions 112, 114, and 116 include the extension regions. Portions of the extension regions can extend under the remaining portions of the first gate electrode layer 42, which are gate electrodes for the transistors within the HV region 11, 1/0 region 13, and logic region 17, and can also extend under the remaining portion of the control gate electrode layer 662, which is a control gate electrode for the NVM cell within the NVM array 15. In the finished electronic devices, each of the S/D regions 112, 114, and 116 has a depth of at least 50 nm, and a concentration at the upper surface that is at least 1E19 atoms/cm³ at locations outside the NVM structure and gate structures 90 and 92, so that ohmic contacts can be formed to the S/D regions 112, 114, and 116.

Processing can be continued to form a substantially completed electronic device. One or more insulating layers, one or more conductive layers, and one or more encapsulating layers are formed using conventional techniques.

The embodiment as described above forms the first gate electrode layer 42 over the first and second gate dielectric layers 24 and 34 before the NVM stack has been formed. Thus, the first and second gate dielectric layers 24 and 34 are less likely to become thickened or adversely oxidized because of forming and patterning the NVM stack 66.

The embodiment can also reduce the number of processing operations that need to be formed. For example, in a conventional process, where the charge storage stack 64 is formed before forming the gate dielectric layers within other regions, a sacrificial protective layer including an oxide film and a nitride film is formed over the substrate 12 to facilitate removal of nanocrystals (within the charge storage layer 644) from regions outside the NVM array 15. An additional mask and etch operation is used to remove portions of the sacrificial protective layer from the NVM array 15 while remaining portions of the sacrificial protective layer cover the other regions. After the NVM cells within the NVM array 15 have been formed, the nanocrystals outside the NVM array 15 are removed along with the remaining portions of the sacrificial protective layer. Because the first anti-reflective layer 44 can function as an etch stop layer and can protect the first gate electrode layer 42 and the first gate dielectric layers 24 and 34 during the charge storage stack 64 removal etch, the sacrificial protective layer is not needed. Furthermore, as the charge storage stack 64 is formed after forming the first and second gate dielectric layers 24 and 34, there is no need for a sacrificial protective layer to protect the charge storage stack during formation of the first and second gate dielectric layers. Therefore, the formation, mask, and etching operations for the sacrificial protective layers are not required. Thus, fabrication costs are reduced, and yield improves due to less handling and processing sequences.

Many alternative embodiments can be used. For example, for a one-time programmable (“OTP”) NVM device, the HV region 11 and I/O region 13 may use the first gate dielectric layer 24. In another embodiment, the HV region 11 may be designed to operate at a higher voltage compared to the I/O region 13. Such a HV region 11 may be present if the NVM array is to be electrically erased (e.g., flash memory). The HV region 11 can have a different well region (e.g., different dopant concentration or concentration gradient), a different gate dielectric layer, or both as compared to the I/O region 13. For example, a fourth gate dielectric layer within the HV region 11 may be thicker than the first gate dielectric layer 24 as used within the I/O region. The fourth gate dielectric layer may be formed before any of the other gate dielectric layers. In still other embodiment, one or more additional well regions, gate dielectric layers, or any combination thereof may be used.

In another embodiment, the well drive cycles are optional or may be consolidated. For example, if subsequent processing has sufficient thermal processing to drive dopants to form the well regions 22, 32, and 62, a separate well drive cycle is not needed. In another embodiment, any combination of well regions may be driven during the same well drive cycle. For example, after forming the doped region 56, a well drive cycle can be used to form the well regions 22, 32, and 62. Alternatively, one well drive cycle can be used to drive a dopant from doped regions 18 and 29 after the doped regions 18 and 29 are formed, and another well drive cycle can be used to drive dopant from doped region 56 to form the well region 62. After reading this specification, skilled artisans will appreciate that they can use any number or no separate well drives that meet their needs or desires.

The embodiment described above works well for electronic devices where each of the HV region 11, I/O region 13, and the logic region 17 has only n-channel or p-channel transistors. In another embodiment, the HV region 11, I/O region 13, the logic region 17, or any combination thereof may include both n-channel and p-channel transistors. Additional processing may be performed so that both n-channel and p-channel transistors are formed in any one or more particular region of the electronic device. After reading this specification, skilled artisans will appreciate how to modify the process flow to integrate n-channel and p-channel transistors within the electronic device.

Note that not all of the activities described above in the general description or the examples are required, that a portion of a specific activity may not be required, and that one or more further activities may be performed in addition to those described. Still further, the order in which activities are listed are not necessarily the order in which they are performed. After reading this specification, skilled artisans will be capable of determining what activities can be used for their specific needs or desires.

In the foregoing specification, principles of the invention have been described above in connection with specific embodiments. However, one of ordinary skill in the art appreciates that one or more modifications or one or more other changes can be made to any one or more of the embodiments without departing from the scope of the invention as set forth in the claims below. Accordingly, the specification and figures are to be regarded in an illustrative rather than a restrictive sense and any and all such modifications and other changes are intended to be included within the scope of invention.

Any one or more benefits, one or more other advantages, one or more solutions to one or more problems, or any combination thereof have been described above with regard to one or more specific embodiments. However, the benefit(s), advantage(s), solution(s) to problem(s), or any element(s) that may cause any benefit, advantage, or solution to occur or become more pronounced is not to be construed as a critical, required, or essential feature or element of any or all the claims.

What is claimed is:

1. A process for forming an electronic device comprising:
forming a first gate dielectric layer over a first region of a substrate;
forming a first gate electrode layer over the first gate dielectric layer; and
forming a non-volatile memory stack over a second region of the substrate after forming the first gate electrode layer.

2. The process of claim 1, further comprising forming a second gate dielectric layer over a third region of the substrate, wherein the second gate dielectric layer has thickness different from the first gate dielectric layer.

3. The process of claim 1, further comprising forming all gate dielectric layers, including the first gate dielectric layer, for all transistors other than any gate dielectric layer within the non-volatile memory stack, before forming the non-volatile memory stack.

4. The process of claim 1, further comprising patterning the first gate electrode layer to define an opening before forming the non-volatile memory stack.

5. The process of claim 4, wherein forming the non-volatile memory stack comprises:
forming a charge storage stack over the substrate and within the opening within the first gate electrode layer; and
forming a control gate electrode layer over the charge storage stack.

6. The process of claim 5, wherein the charge storage stack includes nanocrystals.

7. The process of claim 1, further comprising:
patterning the non-volatile memory stack to define a non-volatile memory structure; and
patterning the first gate electrode layer to define a first transistor structure that comprises the first gate dielectric layer and a portion of the first gate electrode layer, wherein patterning the first gate electrode layer is performed after patterning the non-volatile memory stack.

8. The process of claim 7, further comprising forming a sidewall spacer adjacent to side of the non-volatile memory structure before patterning the first gate electrode layer.

9. The process of claim 7, further comprising:
forming an insulating layer over the substrate after patterning the first gate electrode layer; and
etching the insulating layer, wherein:
a first spacer lies adjacent to a side of the non-volatile memory structure;
a second spacer lies adjacent to a side of the first transistor structure; and
each of the first and second spacers comprises a portion of the insulating layer.

10. The process of claim 1, further comprising
patterning the NVM stack to define an NVM gate structure;
oxidizing a portion of a side of the NVM gate structure;
doping portions of the substrate adjacent to the side of the NVM gate structure before depositing a layer along the side of the NVM gate structure; and
forming a sidewall spacer along the side of the NVM gate structure after doping the portions of the substrate.

11. An electronic device comprising:
a substrate;
a non-volatile memory structure overlying the substrate, wherein the non-volatile memory structure comprises a first gate dielectric layer;
a first spacer having a generally parabolic outer surface, wherein the first spacer lies laterally adjacent to a side of the first gate dielectric layer within the non-volatile memory structure;
a first transistor structure overlying the substrate and spaced apart from the non-volatile memory structure, wherein the first transistor structure comprises a second gate dielectric layer; and
second spacers each having a generally parabolic outer surface, wherein one of the second spacers lies laterally adjacent to a side of the second gate dielectric layer within the first transistor structure, and another second spacer lies laterally adjacent to the generally parabolic outer surface of the first spacer.

12. The electronic device of claim 1 1, wherein the non-volatile memory structure comprises a charge storage stack that includes the first gate dielectric layer and nanocrystals.

13. The electronic device of claim 11, wherein the first and second gate dielectric layers lie at approximately the same elevation along a primary surface of the substrate.

14. A process for forming an electronic device comprising:
forming a non-volatile memory structure over a substrate;
forming a first insulating layer over the substrate after forming the non-volatile memory structure;
etching the first insulating layer to form a first spacer along a side of the non-volatile memory structure;
forming a first transistor structure over the substrate and spaced apart from the non-volatile memory structure after etching the first insulating layer;
forming a second insulating layer over the substrate after forming the first transistor structure; and
etching the second insulating layer to form a second spacer along the side of the first transistor structure, wherein the first spacer comprises a portion of the second insulating layer lying along a side of the first spacer.

15. The process of claim 14, further comprising:
forming a first gate dielectric layer over the substrate before forming the non-volatile memory structure; and
patterning the first gate dielectric layer to define an opening,
wherein forming the non-volatile memory structure comprises forming a non-volatile memory stack within the opening.

16. The process of claim 15, further comprising forming a second gate dielectric layer over the substrate after forming the first gate dielectric layer, wherein the second gate dielectric layer has thickness different from the first gate dielectric layer.

17. The process of claim 15, wherein forming the first transistor structure comprises:
forming a first gate electrode layer over the first gate dielectric layer before forming the non-volatile memory structure; and
patterning the first gate electrode layer to define an opening before forming the non-volatile memory structure,
wherein forming the non-volatile memory structure comprises forming a non-volatile memory stack within the opening within the first gate electrode layer.

18. The process of claim 15, further comprising:
forming a first gate electrode layer over the first gate dielectric layer before forming the non-volatile memory structure; and
patterning the first gate electrode layer after forming the non-volatile memory structure to define a first transistor structure that comprises the first gate dielectric layer and a portion of the first gate electrode layer

19. The process of claim 14, further comprises forming all gate dielectric layers, including the first gate dielectric layer, for all transistors other than any non-volatile memory cell, before forming the non-volatile memory structure.

20. The process of claim 14, wherein forming the non-volatile memory structure comprises forming a charge storage stack that includes nanocrystals.
